(19) United States
(12) Patent Application Publication
(10) Pub. No.: US 2015/0064930 A1
(43) Pub. Date: Mar. 5, 2015

(54) PROCESS OF MANUFACTURING THE GATE OXIDE LAYER

(71) Applicant: Shanghai Huali Microelectronics Corporation, Shanghai (CN)

(72) Inventors: ZHONGPING LI, SHANGHAI (CN); ZHI WANG, SHANGHAI (CN); JINMING SU, SHANGHAI (CN); HSUSHENG CHANG, SHANGHAI (CN)

(73) Assignee: Shanghai Huali Microelectronics Corporation, Shanghai (CN)

(21) Appl. No.: 14/082,310

(22) Filed: Nov. 18, 2013

(30) Foreign Application Priority Data
Sep. 2, 2013 (CN) 201310393733.1

(51) Int. Cl. H01L 21/02; H01L 21/28

(52) U.S. Cl. CPC H01L 21/02233; H01L 21/28167
USPC 438/773

(57) ABSTRACT

A process of manufacturing the gate oxide layer, which uses the wet oxidation by deuterium to form gate oxide layer, wherein the nitriding treatment is applied to formed gate oxide layer by high temperature annealing process, the stable Si-D bonds is formed on surface of the gate oxide layer to reduce silicon dangling bonds, which reduce the defect of the gate oxide interface and lower the interface defect density of the gate oxide layer and the charge density effectively to avoid NBTI, is provided.

### CROSS-REFERENCE TO RELATED APPLICATIONS

The present application claims priority under the Paris Convention to Chinese application number CN 201310393733.1, filed on Sep. 2, 2013, the disclosure of which is here with incorporated by reference in its entirety.

### FIELD OF TECHNOLOGY

The following relates to a field of Semiconductor manufacturing, more specifically, it relates to a process of manufacturing the gate oxide layer.

### BACKGROUND

Negative Bias Temperature Instability (abbreviation: NBTI) is a series of electrical parameter degradation triggered by the negative gate voltage, which is applied to PMOSFET at high temperature generally, in the stress condition at the constant temperature of 125° C. of the gate oxide electric field, of the source electrode, of the drain electrode and of substrate earth.

NBTI effects comprise the generation and the passivation of positive charge, i.e., the generation of the interface trapped charge, the positive charge fixed on the oxide layer and the diffusing process of diffusing material. Hydrogen and water vapor are two main material results in NBTI. NBTI effect substantively impairs the devices and the circuits, such as increasing the gate current of the device, the negative drift of threshold voltage, decreasing of the subthreshold slope, transconductance, decreasing of the leakage and so on. NBTI effect also results in the cause the mismatch of the transistors in analog circuits and the timing drift decrease of the noise margin and the product failure in digital circuit.

With the development of the process of semiconductor devices, the requirement of the device performance becomes higher and higher. The size of device becomes smaller and smaller. However, with the reduce of the device size, the working voltage is not reduced proportionally. It increases electric field of gate oxide layer, where NBTI is triggered easily. Particularly, the gate oxide layer is adopted the traditional wet-oxygen oxide Si+H₂O→SiO₂). The interface of the gate oxide layer includes a huge number of Si—H bonds which are easily to generate H atoms in hole under the thermal excitation and to leave dangling bond on the interface. Due to the instability of H atoms, i.e., two H atoms is easily to react into H2, released in the form of hydrogen molecules. H2 diffuse far to the surface of gate, which causes the negative drift of threshold voltage, forms NBTI effect, decreases the performance of the device and even impairs the device.

Chinese Patent (Publication Number: CN 1264164A) disclosed a method for forming the gate oxide of a Metal-Oxide-Semiconductor (MOS). It adopts a process of dry, wet and dry oxide of semiconductor. This method results in reducing the interface state density at the semiconductor-oxide interface. However, it did not disclose the solution to eliminate NBTI effects.

Chinese patent (Publication Number: CN 1722408 A) discloses a method of forming the gate oxide film forms. It forms dielectric film on the substrate. The sacrifice or the gate oxide film is formed to be used as oxide film. The resist layer is used as mask, as a result, the ion implanting layer is formed with one or more implanting process by argon or fluorine ions through the oxide film. Moreover, when the oxide film is used as the sacrifice oxide film after the resist layer and the oxide layer forms is removed, the gate oxide film is formed in the device port. When the oxide film is used as the gate oxide film, the oxide film is etched once to reduce the thickness. It thickens the oxide film after removing the resist layer, due to the forming the ion implanting layer to form the thick gate oxide film. The patent did not disclose the solution for NBTI.

### SUMMARY

Due to the defects of the traditional art, the present invention discloses a method of a process of manufacturing the gate oxide layer, which adopts the furnace tube to form the said gate oxide layer, comprising;

a process of dry oxidation and a process of wet oxidation are applied to a semiconductor substrate in sequence to form a gate oxide layer;

the gate oxide layer is annealed by nitrogen in a high temperature;

wherein oxygen gas is applied to the said dry oxidation, deuterium is applied to the said wet oxidation.

According to the above method, it comprises that after the said wet oxidation, the said dry oxidation is applied to the said semiconductor substrate to form the said gate oxide layer.

According to the above method, wherein the temperature of the said dry oxidation is 700° C. to 900° C., and the flow of oxygen gas supplied is larger than or equals to 1 slm.

According to the above method , wherein the temperature of the said wet oxidation is 700° C. to 900° C., the time is 25 min-35 min.

According to the above method, wherein the ratio of gas flow of deuterium and oxygen is 1:2-2:1 when the said wet oxidation is in process.

According to the above method, wherein value of the high temperature is larger than or equals to 900° C.

According to the above method, wherein the gate oxide layer is annealed by nitrogen of which flow is larger than or equals to 5 slm.

According to the above method, wherein the time when the gate oxide layer is annealed is 10 minutes to 15 minutes.

According to the above method, wherein further comprising:

after the loading process is applied to the said substrate, the increasing rate of the temperature ranges from 7° C. per minute to 13° C. per minute, the temperature of the reactor chamber will be raised to the said temperature required by the dry oxidation process, meanwhile, the flow of oxygen to be larger than or equals to 0.3 slm.

According to the above method, wherein comprises as follows:

Before the said annealing process is applied to the said substrate, the increasing rate of the temperature is 7° C./min-13° C./min, the temperature of the reactor chamber will rise to the said temperature required by the annealing process;

before the unloading process is applied to the said substrate, the decreasing rate of the temperature is 1° C./min-5° C./min, the temperature of the reactor chamber will drop to the said temperature required by the unloading process;

The advantageous effects of the above technical solution are as follows: In conclusion, the present invention, a process of forming the gate oxide layer, which adopts wet oxidation by deuterium to form the gate oxide layer. The nitriding treatment is applied to form the gate oxide layer by the annealing process of high temperature. The stable Si-D bonds is formed on surface of the gate oxide layer to reduce silicon dangling bonds, which reduces the defect of the gate oxide interface and lowers the interface defect density of the gate oxide layer and the charge density effectively to avoid NBTI. Consequently, the reliability and yield of product is improved.

### BRIEF DESCRIPTION

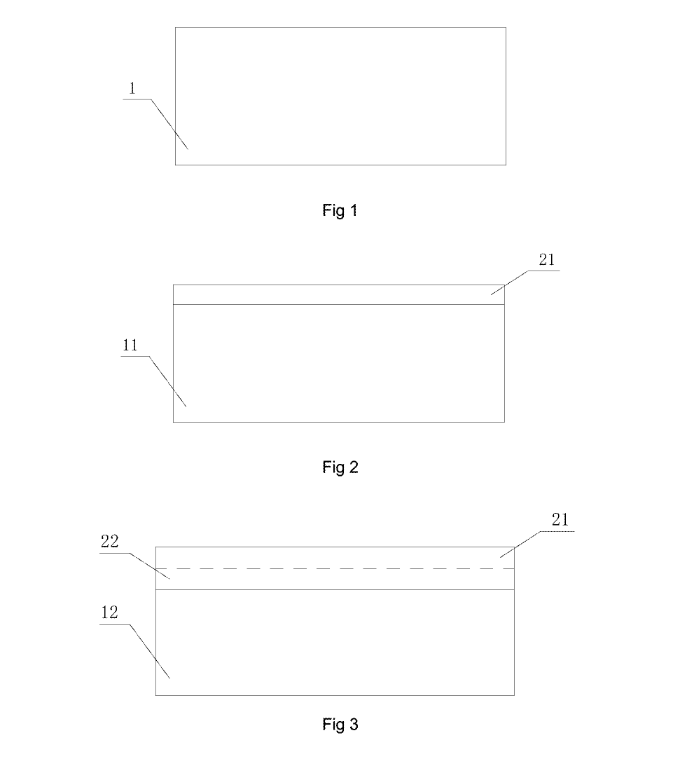

FIGS. 1-5 are the structure diagrams of the process of forming the gate oxide layer.

### DETAILED DESCRIPTION

The present invention will be further illustrated in combination with the following figures and embodiments, but it should not be deemed as limitation of the present invention.

FIGS. 1-5 are the structure diagrams of the process of forming the gate oxide layer. As shown in FIGS. 1-5, a process which forms the gate oxide film adopts furnace tube to form the said gate oxide layer. Firstly, as shown in FIG. 1, a loading process (LOAD) is applied to a Substrate 1 in the temperature of 600° C. through the process of stabilization (STAB). The temperature rises where the increasing rate of temperature is 7° C./min-13° C./min, such as 7° C./min, 10° C./min or 13° C./min and so on. The temperature of the reactor chamber will ramp up to the temperature of 700° C. to 900° C., such as 700° C., 800° C., or 900° C. and so on, stabilizing the team (TEAM STAB), which satisfies the temperature requirement in the follow-up dry oxidation. Meanwhile, the appropriate oxygen gas is supplied to the reactor chamber. The flow of the oxygen gas is larger than or equals to 0.3 slm, such as 0.3 slm, 0.5 slm or 0.8 slm and so on.

Secondly, the dry oxidation (DRY OXIDE) is applied to the Semiconductor Substrate 1, then a First Gate Oxide Layer 21 is formed on the upper surface of the semiconductor substrate, which covers the upper surface of a first remaining Semiconductor Substrate 11. And then the structure is formed as shown in FIG. 2; wherein, the dry oxidation lasts 15 min to 25 min, such as 15 min, 20 min or 25 min and so on at the temperature of 700° C. to 900° C., such as 700° C., 850° C. or 900° C. and so on. Meanwhile, the flow of the oxygen gas which is introduced into the reactor chamber is larger than or equals to 1 slm, such as 1 slm, 3 slm or 5 slm and so on.

Next, the wet oxidation (WET+DCE) is applied to the first remaining Semiconductor Substrate 11 so that a Second Gate Oxide Layer 22 is formed at the upper surface of the first remaining semiconductor Substrate 11, and Second Gate Oxide Layer 22 covers the upper surface of a second remaining gate oxide layer 12. The First Gate Oxide Layer 21 covers the upper surface of the Second Gate Oxide Layer 22. The structure is formed as shown in FIG. 3. The stable Si-D bonds (Si+D₂O →SiO₂) is formed in the gate oxide layer, which can reduce the silicon dangling bonds. Consequently, the goal for reducing defect is achieved; wherein, the wet oxidation last 25 min to 35 min, such as 25 min, 30 min or 35 min and so on at the temperature of 700° C. to 900° C., such as 700° C., 800° C. or 900° C. and so on. Meanwhile, deuterium gas is supplied to the reactor chamber, the ratio of gas flow of deuterium gas and oxygen gas is 1:2-2:1, such as 1:2, 1:1 or 2:1 and so on.

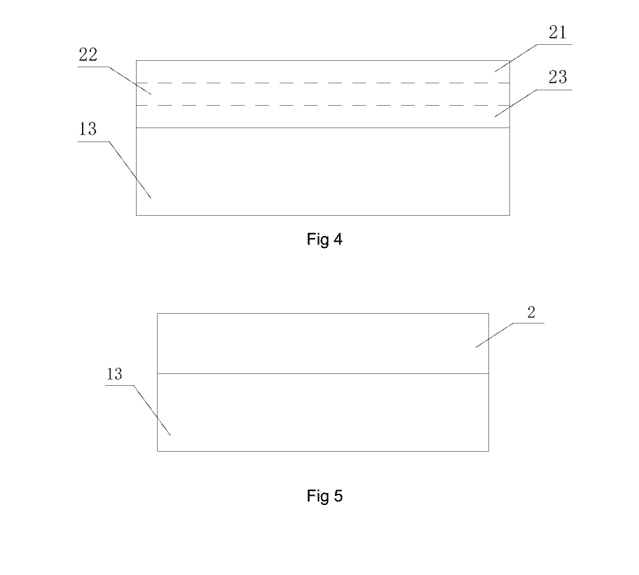

Then, the dry oxidation (DRY OXIDE) is applied to the second remaining Semiconductor Substrate 12, so that Third Gate Oxide Layer 23 is formed at the upper surface of the second remaining Semiconductor Substrate 12. Third gate oxide layer 23 covers the upper surface of the Third Gate Oxide Layer 13. The Second Gate Oxide Layer 22 covers the upper surface of Third Gate Oxide Layer 23. The structure is formed as shown in FIG. 4. As shown in FIGS. 4 and 5, First Gate Oxide Layer 21, Second Gate Oxide Layer 22 and Third Gate Oxide Layer 23 make up of Gate Oxide Layer 2; wherein, the dry oxidation last 3 min to 7 min (such as 3 min, 5 min or 7 min and so on at the temperature of 700° C. to 900° C., such as 700° C., 800° C. or 900° C. and so on. Meanwhile, the flow of the supplied oxygen gas in reactor chamber is larger than or equals to 1 slm, such as 1 slm, 3 slm or 5 slm and so on.

The temperature rises, and the increasing rate of temperature is still 7° C./min-13° C./min, such as 7° C./min, 10° C./min or 13° C./min and so on. The temperature of the reactor chamber will ramp up the temperature which is larger than or equals to 900° C., such as 900° C., 1000° C. or 1100° C. and so on, which satisfies the temperature requirement of the follow-up annealing process.

At last, when the temperature is larger than or equals to 900° C. (such as 900° C., 1000° C. or 1100° C. etc), the annealing process which is applied to the gate oxide layer 2 lasts 10 min to 25 min (such as 10 min, 15 min or 25 min etc) with nitrogen gas whose flow is great than or equals to 5 slm (such as 5 slm, 7 slm [symbol] 9 slm etc), and the gate oxide layer 2 is treated by the nitriding treatment so as to reduce the interface detect density and the charge density of the gate oxide layer 2;

Then the temperature drops, and the decreasing rate of the temperature is still 1° C./min-5° C./min (such as 1° C./min, 3° C./min or 5° C./min etc), the temperature of the reactor chamber will ramp down about 600° C. to finish follow-up unloading process.

Although a typical embodiment of a particular structure of the specific implementation way has been given with the above description and the figures, it is appreciated that other changes based on the spirit of this invention may also be made. Though the preferred embodiments are proposed above, these contents will never be the limitation of this invention.

The Claims attached may incorporate changes and modifications which cover the intention and the range of this invention. Any and all equivalent contents and ranges in the range of the Claims should be regarded belonging to the intention and the range of this invention.

1. A process which forms a gate oxide film, which adopts a furnace tube to form the gate oxide layer, comprising:
a process of dry oxidation and a process of wet oxidation are applied to a semiconductor substrate in sequence to form a gate oxide layer, wherein the gate oxide layer is annealed by nitrogen in a high temperature;
wherein oxygen gas is applied to the dry oxidation, and deuterium is applied to the wet oxidation.

2. The method according to claim 1, wherein after the wet oxidation, the dry oxidation is applied to the semiconductor substrate to form the gate oxide layer.

3. The method according to claim 1, wherein a temperature of the dry oxidation is 700° C. to 900° C., and a flow of the oxygen gas supplied is larger than or equals to 1 standard liter per minute (slm).

4. The method according to claim 2, wherein a temperature of the dry oxidation is 700° C. to 900° C., and a flow of the oxygen gas supplied is larger than or equals to 1 slm.

5. The method according to claim 1, wherein a temperature of the wet oxidation is 700° C. to 900° C., and a time is 25 min-35 min.

6. The method according to claim 1, wherein a ratio of gas flow of deuterium and oxygen is 1:2-2:1 when the wet oxidation is in process.

7. The method according to claim 1, wherein a value of a high temperature is larger than or equal to 900° C.

8. The method according to claim 1, wherein the gate oxide layer is annealed by nitrogen of which a flow is larger than or equal to 5 slm.

9. The method according to claim 1, wherein a time when the gate oxide layer is annealed is 10 minutes to 15 minutes.

10. The method according to claim 1, further comprising:
after the loading process is applied to the semiconductor substrate, an increasing rate of a temperature ranges from 7° C. per minute to 13° C. per minute, wherein the temperature of a reactor chamber is raised to the temperature required by the dry oxidation process, meanwhile, a flow of oxygen is larger than or equal to 0.3 slm.

11. The method according to claim 1, further comprises:
before the annealing process is applied to the semiconductor substrate, an increasing rate of a temperature is 7° C./min-13° C./min, wherein the temperature of a reactor chamber rises to the temperature required by the annealing process; and
before the unloading process is applied to the semiconductor substrate, a decreasing rate of the temperature is 1° C./min-5° C./min, wherein the temperature of the reactor chamber drops to the temperature required by the unloading process.
